(19) United States
(12) Patent Application Publication
(10) Pub. No.: US 2024/0090142 A1
(43) Pub. Date: Mar. 14, 2024

(54) ELECTRONIC APPARATUS AND ADAPTER

(71) Applicant: NEC Corporation, Tokyo (JP)

(72) Inventor: Tatsuhiro Nakada, Tokyo (JP)

(73) Assignee: NEC Corporation, Tokyo (JP)

(21) Appl. No.: 18/205,759

(22) Filed: Jun. 5, 2023

(30) Foreign Application Priority Data
Sep. 14, 2022 (JP) 2022-145876

(51) Int. Cl. H05K 5/02; H05K 5/00; H05K 7/20

(52) U.S. Cl. CPC H05K 5/0204; H05K 5/0021; H05K 5/0213; H05K 5/0247; H05K 7/202

(57) ABSTRACT

An electronic apparatus according to the present invention includes a substrate and an adapter, the substrate includes a flow path adjustment plate that adjusts a stream of gas in such a way that the gas flows in a first direction, and the adapter includes a first connector connectable, in a second direction perpendicular to the first direction, to the substrate, a second connector protruding in a direction parallel to the first direction, a circuit electrically connecting the first connector to the second connector, and a holding member holding the first connector, the second connector and the circuit, and being in contact with a part of a periphery of the substrate due to connection of the first connector to the substrate.

This application is based upon and claims the benefit of priority from Japanese Patent Application No. 2022-145876, filed on Sep. 14, 2022, the disclosure of which is incorporated herein in its entirety by reference.

### TECHNICAL FIELD

The present invention relates to, for example, an adapter being connectable to a substrate, and the like.

### BACKGROUND ART

In a general communication system, a rack is used in which a plurality of cards on which an electronic apparatus such as a circuit is mounted are installed. An air-cooling device such as a fan installed inside the rack sucks in air from outside of the rack, exhausts the sucked air, and thereby cools the cards.

For example, Japanese Translation of PCT International Publication for Patent Application, No. 2003-522422 discloses a system in which a laterally installable card is longitudinally passed and connected to a chassis in a computer while remaining cards of the computer system remain under an operating state.

As described above, a rack in a general communication system cools a card by using air. In this case, in order to cool the card efficiently, for example, an air flow path is provided on the card. However, an air intake direction and an air exhaust direction are different for each type of rack.

Therefore, a direction of the flow path provided on the card may be different from an air intake direction and an air exhaust direction of the rack. In such a case, there is a problem that air inside the rack does not efficiently flow through the flow path provided on the card. In view of the above-described problems, an example object of the present invention

### SUMMARY

In view of the above-described problems, an example object of the present invention is to provide an electronic apparatus capable of flowing air in a rack through a flow path provided on a card with more efficiency.

According to an example aspect of the present invention, there is provided an electronic apparatus of the present invention is an electronic apparatus including a substrate and an adapter, the substrate includes a flow path through which gas flows in a first direction, and the adapter includes, a first connector connectable to the substrate in a second direction perpendicular to the first direction, a second connector protruding in a direction parallel to the first direction, a circuit electrically connecting the first connector and the second connector and a holding member holding the first connector, the second connector, and the circuit, and being in contact with a part of a periphery of the substrate due to connection of the first connector to the substrate.

### BRIEF DESCRIPTION OF THE DRAWINGS

Exemplary features and advantages of the present invention will become apparent from the following detailed description when taken with the accompanying drawings in which:

FIG. 1 is a schematic diagram illustrating a configuration example of an electronic apparatus according to a first example embodiment of the present invention.

FIG. 2 is a diagram illustrating details of the electronic apparatus according to the first example embodiment of the present invention.

FIG. 3 is a diagram illustrating details of the electronic apparatus according to the first example embodiment of the present invention.

FIG. 4 is a schematic diagram illustrating a configuration example of an electronic apparatus according to a second example embodiment of the present invention.

FIG. 5 is a schematic diagram illustrating a modification example of the electronic apparatus according to the second example embodiment of the present invention.

FIG. 6 is a schematic diagram illustrating a modification example of the electronic apparatus according to the second example embodiment of the present invention.

FIG. 7 is a schematic diagram illustrating a configuration example of an electronic apparatus according to a third example embodiment of the present invention.

### EXAMPLE EMBODIMENT

Preferred example embodiments of the present invention will be described in detail with reference to the drawings.

### First Example Embodiment

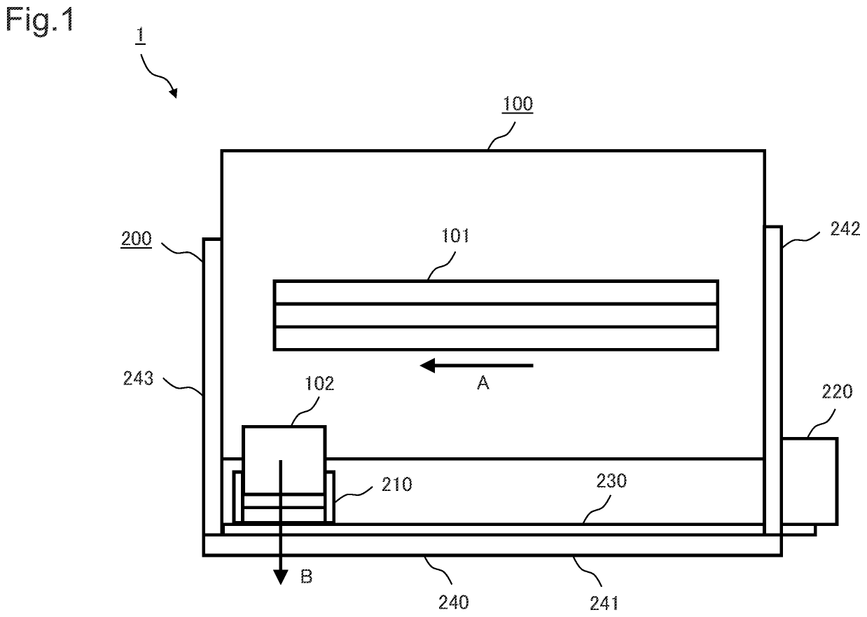

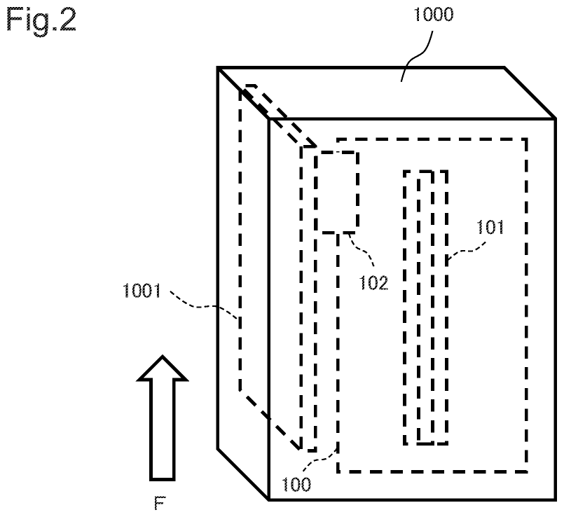

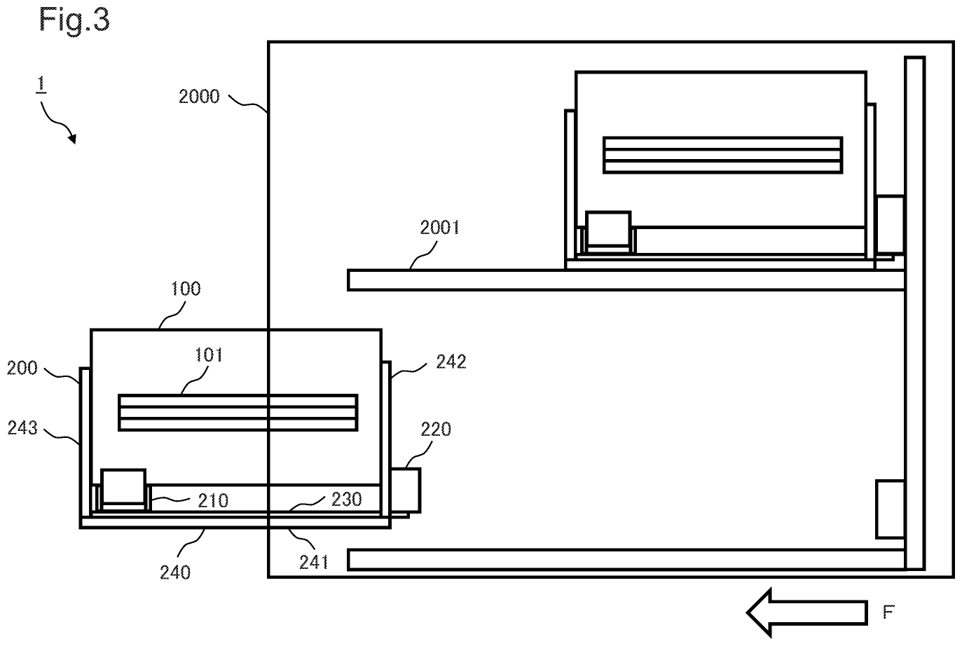

An electronic apparatus 1 according to a first example embodiment is described based on FIG. 1, FIG. 2, and FIG. 3. FIG. 1 is a schematic diagram illustrating a configuration example of the electronic apparatus 1. FIG. 2 and FIG. 3 are schematic diagrams illustrating details of the electronic apparatus 1.

A configuration of the electronic apparatus 1 is described. As illustrated in FIG. 1, the electronic apparatus 1 includes a substrate 100 and an adapter 200. The substrate 100 connects to the adapter 200. The electronic apparatus 1 is, for example, a card mounted in a rack installed in a landing station of a submarine cable system or in a data center.

The substrate 100 includes a flow path adjustment plate 101 that adjusts a stream of gas in such a way that the gas flows in a first direction. The first direction is a direction indicated by allow A in FIG. 1. The flow path adjustment plate 101 is, for example, a heat sink fixed to the substrate 100, a fin formed on the substrate 100, or the like. In this case, a direction of extension of the fin is set to be parallel to the first direction. Other than the flow path adjustment plate 101, an unillustrated heat-generating body such as a central processing unit (CPU), a circuit, and the like may be provided on the substrate 100. Further, the substrate 100 includes a protrusive unit 102. For example, the protrusive unit 102 is connected to the adapter 200, as illustrated in FIG. 1.

Further, the adapter 200 includes a first connector 210, a second connector 220, a circuit 230, and a holding member 240. Further, the holding member 240 includes a first base member unit 241, a second base member unit 242, and a third base member unit 243.

As illustrated in FIG. 1, the first connector 210 is, for example, a recess-shaped connecter. The first connector 210 is electrically connected to the circuit 230. Further, the first connector 210 is held by the holding member 240. The first connector 210 is a connecter that is connectable to the substrate 100 in a second direction, which is perpendicular to the first direction. The second direction is a direction indicated by arrow B in FIG. 1. For example, as illustrated in FIG. 1, the protrusive unit 102 formed on the substrate 100 is inserted in the first connector 210, and thereby the first connector 210 connects to the substrate 100.

As illustrated in FIG. 1, the second connector 220 is a convex-shaped connecter. The second connector 220 is electrically connected to the circuit 230. Further, the second connector 220 is held by the holding member 240. The second connector 220 is a connecter protruding in a direction parallel to the above-described first direction.

As illustrated in FIG. 1, the circuit 230 is provided on the holding member 240. The circuit 230 electrically connects the first connector 210 to the second connector 220. An electric signal that is input from the substrate 100 to the first connector 210 is input to the second connector 220 via the circuit 230.

As illustrated in FIG. 1, the holding member 240 includes the first base member unit 241, the second base member unit 242, and the third base member unit 243. The holding member 240 holds the first connector 210, the second connector 220, and the circuit 230. Further, the holding member 240 is in contact with a part of a periphery of the substrate 100 due to connection of the first connector 210 to the substrate 100. Note that, the holding member 240 is formed of a metal material such as aluminum, a resin material such as acrylonitrile butadiene styrene (ABS) copolymer synthetic resin, and the like.

The first base member unit 241 holds the first connector 210 and the circuit 230. Further, the first base member unit 241 is connected to the second base member unit 242 and the third base member unit 243. The second base member unit 242 is connected to the first base member unit 241 and holds the second connector 220. Further, the third base member unit 243 is connected to the first base member unit 241 and is parallel to the second base member unit 242.

At least one of the second base member unit 242 and the third base member unit 243 is in contact with a part of one of a plurality of sides included in the periphery of the substrate 100. Specifically, as illustrated in FIG. 1, the second base member unit 242 is in contact with one side of the plurality of sides included in the periphery of the substrate 100. The second base member unit 242 is not necessarily in contact with the entire of the one side and is in contact with a part of the one side, as illustrated in FIG. 1. Further, as illustrated in FIG. 1, the third base member unit 243 is in contact with one of the plurality of sides included in the periphery of the substrate 100. The third base member unit 243 is not necessarily in contact with the entire of the one side and is in contact with a part of the one side, as illustrated in FIG. 1.

As described above, the electronic apparatus 1 includes the adapter 200 including the first connector 210, the second connector 220, the circuit 230, and the holding member 240. The first connector 210 is connectable, in the second direction perpendicular to the first direction, to the substrate 100 including the flow path adjustment plate 101 that adjusts a stream of gas in such a way that the gas flows in the first direction. Further, the second connector 220 protrudes in a direction parallel to the first direction. The circuit 230 electrically connects the first connector 210 to the second connector 220. The holding member 240 holds the first connector 210, the second connector 220, and the circuit 230, and is in contact with a part of the periphery of the substrate 100 due to connection of the first connector 210 to the substrate 100.

FIG. 2 is a diagram for describing a method in which the substrate 100 is accommodated in a first rack 1000. The first rack 1000 includes a first accommodation means 1001 capable of accommodating a plurality of cards such as the substrate 100. Further, the first rack 1000 includes an unillustrated air-cooling means. The air-cooling means causes air to flow between two bases of the first rack 1000. In an example illustrated in FIG. 2, the air-cooling means flows air in a direction from bottom to top in FIG. 2 (a direction indicated by allow F in FIG. 2).

Referring to FIG. 2, when the substrate 100 is to be accommodated in the first rack 1000, the protrusive unit 102 of the substrate 100 is connected to the first rack 1000 without using the adapter 200, and thereby the substrate 100 is accommodated in the first rack 1000. As illustrated in FIG. 2, the substrate 100 is attached to the first accommodation means 1001 in a longitudinal direction (a direction in which a surface of the substrate 100 becomes parallel to arrow F in FIG. 2) via the protrusive unit 102. Thereby, as illustrated in FIG. 2, the substrate 100 is accommodated in the first rack 1000 in a state in which the first direction, which is a direction in which the flow path adjustment plate 101 flows gas, is parallel to the direction (arrow F in FIG. 2) in which the air-cooling means flows air.

FIG. 3 is a diagram for describing a method in which the substrate 100 is accommodated in a second rack 2000. The second rack 2000 includes a second accommodation means 2001 capable of accommodating a plurality of cards such as the substrate 100. Further, the second rack 2000 includes an unillustrated air-cooling means. The air-cooling means herein is, for example, a fan. Note that, the air-cooling means may be provided outside the second rack 2000. The air-cooling means cause air to flow between two lateral faces of the second rack 2000. In the example illustrated in FIG. 3, the air-cooling means flows air in a direction from right to left in FIG. 3 (a direction indicated by arrow F in FIG. 3).

When the substrate 100 is to be accommodated in the second rack 2000, as illustrated in FIG. 3, the adapter 200 is used. As illustrated in FIG. 3, the substrate 100 connects to the adapter 200 in a lateral direction via the first connector 210. Further, the adapter 200 and the substrate 100 connect to the second accommodation means 2001 via the second connector 220. Thereby, as illustrated in FIG. 3, the substrate 100 is accommodated in the second rack 2000 in a state in which the first direction, which is a direction in which the flow path adjustment plate 101 flows gas, is parallel to the direction in which the air-cooling means flows air (the direction indicated by arrow F in FIG. 3).

As described above, the electronic apparatus 1 includes the substrate 100 including the flow path adjustment plate 101 that adjusts a stream of gas in such a way that the gas flows in the first direction, and includes the first connector 210 connectable to the substrate 100 in the second direction, which is perpendicular to the first direction. Further, the electronic apparatus 1 includes the second connector 220 protruding in a direction parallel to the first direction.

Therefore, according to the electronic apparatus 1, by switching whether to use the adapter 200, in all racks of which directions in which the substrate 100 is to be attached are different from each other, the substrate 100 is accommodated in each of the racks in a state in which a direction in which the air-cooling means flows air is parallel to the first direction (the direction indicated by arrow F in FIG. 3) in which the flow path adjustment plate 101 flows air.

In the example illustrated in FIG. 1, although the first connector 210 is described to be recess-shaped, the first connecter 210 may be convex-shaped. In this case, instead of connecting to the adapter 200 via the protrusive unit 102, the substrate 10 connects to the adapter 200 via the recess-shaped connector provided in place of the protrusive unit 102.

Further, in the example illustrated in FIG. 1, although the second connector 220 is described to be convex-shaped, the second connector 220 may be recess-shaped. In this case, the adapter 200 is connected to a rack by connecting the second connector 220 to a convex-shaped member provided in the rack.

### Second Example Embodiment

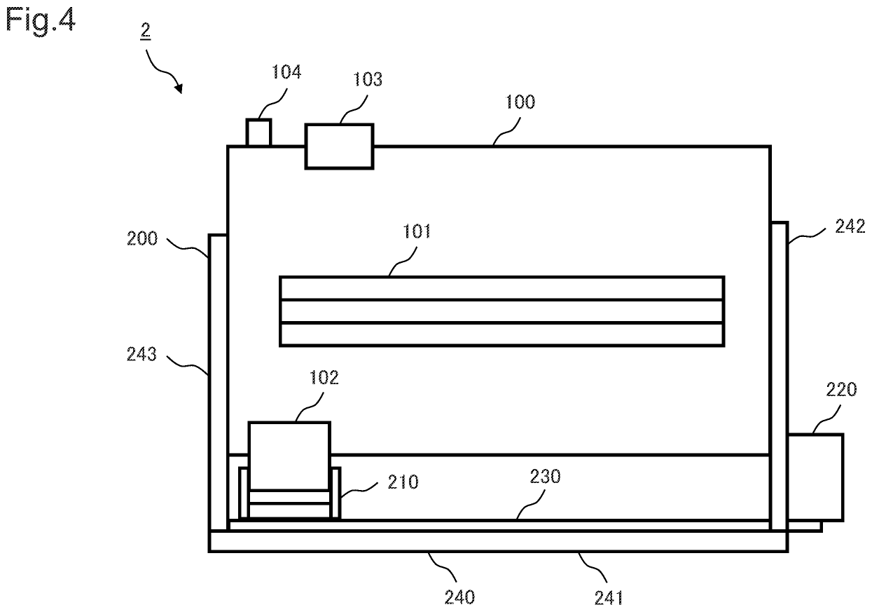

An electronic apparatus 2 according to a second example embodiment is described based on FIG. 4. FIG. 4 is a schematic diagram illustrating a configuration example of the electronic apparatus 2. Similarly to the electronic apparatus 1, the electronic apparatus 2 includes a substrate 100 and an adapter 200. The electronic apparatus 2 differs from the electronic apparatus 1 in that the substrate 100 further includes a DIP switch 103 and a light emitting diode (LED) 104. The DIP switch 103 and the LED 104 correspond to an interface to an outside.

The DIP switch 103 is a switch for controlling unillustrated circuits and an unillustrated electronic apparatus that are provided on the substrate 100. A user operates the DIP switch 103, and can thereby switch connection relationships between the circuits and on and off of the electronic apparatus.

The LED 104 indicates a status of the substrate 100. For example, when an anomaly is detected in any one of the circuits and the electronic apparatus on the substrate 100, the LED 104 blinks repeatedly.

The substrate 100 includes the interface to the outside at a part of a periphery of the substrate 100 that is not in contact with a holding member 240. The interface to the outside, such as the DIP switch 103 and the LED 104 described above, is preferably provided at a position that easily visible to the user. The substrate 100 includes such an interface to the outside at a part that is not in contact with the holding member 240, and thereby interference between the interface to the outside and the holding member 24 is reduced in the electronic apparatus 2. Specifically, occurrence of a situation in which the LED 104 is covered by the holding member 240 can be suppressed.

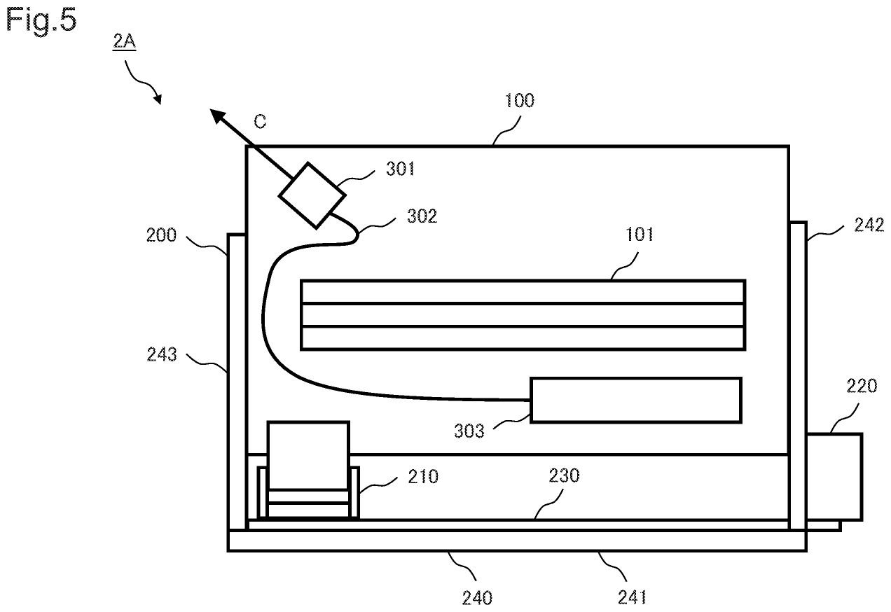

Next, an electronic apparatus 2A is described with reference to FIG. 5. FIG. 5 is a schematic diagram illustrating a configuration example of the electronic apparatus 2A. The electronic apparatus 2A is a modification example of the electronic apparatus 2. Similarly to the electronic apparatus 1, the electronic apparatus 2A includes the substrate 100 and the adapter 200. The electronic apparatus 2A differs from the electronic apparatus 1 in that the substrate 100 further includes an optical adapter 301, an optical fiber 302, and an optical transceiver 303. The optical adapter 301 corresponds to an optical output unit that is capable of outputting light.

The optical adapter 301, the optical fiber 302, and the optical transceiver 303 are attached to the substrate 100. The optical adapter 301 is optically connected to the optical fiber 302. The optical fiber 302 is optically connected to the optical adapter 301 and the optical transceiver 303. The optical transceiver 303 is optically connected to the optical fiber 302.

The optical transceiver 303 outputs an optical signal to the optical fiber 302. The optical signal propagates in the optical fiber 302, and is output from the optical adapter 301. The optical adapter 301 is capable of outputting light to the outside. The optical adapter 301 is further equipped with an unillustrated optical fiber, and the optical signal is output to the outside via the optical fiber.

A direction in which light is output from the optical output unit is a third direction that is not parallel to the first direction and the second direction described above. Specifically, the third direction is a direction indicated by arrow C in FIG. 5.

As described above, a first connector 210 is connectable to the substrate 100 in the second direction, which is perpendicular to the first direction. Further, a second connector 220 protrudes in a direction parallel to the first direction.

Therefore, for example, when removing the substrate 100 from the first rack 1000 illustrated in FIG. 2, a user tends to be in a position parallel to the first direction from the substrate 100. Further, when removing the substrate 100 from the second rack 2000 illustrated in FIG. 3, a user tends to be in a position parallel to the second direction from the substrate 100.

In the electronic apparatus 2A, a direction in which light is output from the optical output unit is the third direction, which is not parallel to the first direction and the second direction described above. Therefore, even when light is output from the optical output unit while a use removes the substrate 100 from a rack, it can be suppressed that the light directly enters eyes of the user.

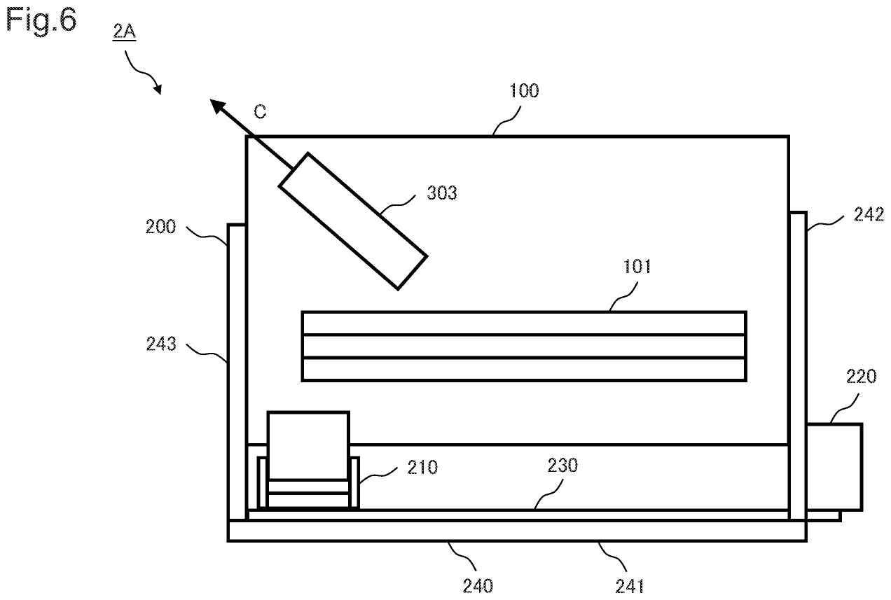

Further, as illustrated in FIG. 6, the electronic apparatus 2A may include the optical transceiver 303 without including the optical adapter 301 and the optical fiber 302. In this case, the optical transceiver 303 corresponds to the optical output unit that is capable of outputting light.

### Third Example Embodiment

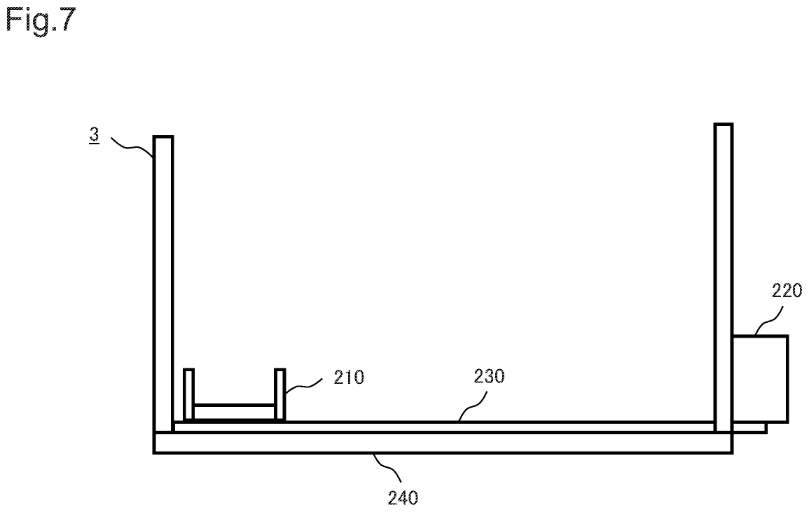

An adapter 3 according to a third example embodiment is described based on FIG. 7. FIG. 7 is a schematic diagram illustrating a configuration example of the adapter 3.

As illustrated in FIG. 7, the adapter 3 includes a first connector 210, a second connector 220, a circuit 230, and a holding member 240.

The first connector 210 is connectable, in a second direction perpendicular to a first direction, to a substrate including a flow path adjustment plate that adjusts a stream of gas in such a way that the gas flows in the first direction. The second connector 220 protrudes in a direction parallel to the first direction. The circuit 230 electrically connects the first connector 210 to the second connector 220. The holding member 240 holds the first connector 210, the second connector 220, and the circuit 230, and is in contact with a part of a periphery of the substrate due to connection of the first connector 210 to the substrate.

As described above, the adapter 3 includes the first connector 210 connectable to the substrate in the second direction perpendicular to the first direction. Further, the adapter 3 includes the second connector 220 protruding in the direction parallel to the first direction.

Therefore, according to the adapter 3, by switching whether to use the adapter 3, in all racks of which directions in which the substrate is to be attached are different from each other, it is possible to accommodate the substrate in each of the rack in a state in which the first direction is parallel to a direction in which air flows.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

1. An electronic apparatus comprising a substrate and an adapter, wherein
the substrate includes a flow path adjustment plate that adjusts a stream of gas in such a way that the gas flows in a first direction, and
the adapter includes:
a first connector connectable to the substrate in a second direction perpendicular to the first direction;
a second connector protruding in a direction parallel to the first direction;
a circuit electrically connecting the first connector to the second connector; and
a holding member holding the first connector, the second connector and the circuit, and being in contact with a part of a periphery of the substrate due to connection of the first connector to the substrate.

2. The electronic apparatus according to claim 1, wherein
the holding member includes:
a first base member unit holding the first connector and the circuit;
a second base member unit being connected to the first base member unit and holding the second connector; and
a third base member unit being connected to the first base member unit and being parallel to the second base member unit, and
at least one of the second base member unit and the third base member unit is in contact with a part of one side of a plurality of sides included in the periphery of the substrate.

3. The electronic apparatus according to claim 1, wherein
the substrate includes an interface to an outside at a part of the periphery that is not in contact with the holding member.

4. The electronic apparatus according to claim 1, wherein
the substrate further includes an optical output unit capable of outputting light, and
a direction in which the light is output from the optical output unit is a third direction that is not parallel to the first direction and the second direction.

5. An adapter comprising:
a first connector connectable, in a second direction perpendicular to a first direction, to a substrate including a flow path in which gas flows in the first direction;
a second connector protruding in a direction parallel to the first direction;
a circuit electrically connecting the first connector to the second connector; and
a holding member holding the first connector, the second connector and the circuit, and being in contact with a part of a periphery of the substrate due to connection of the first connector to the substrate.

6. The adapter according to claim 5, wherein
the holding member includes:
a first base member unit holding the first connector and the circuit;
a second base member unit being connected to the first base member unit and holding the second connector; and
a third base member unit being connected to the first base member unit and being parallel to the second base member unit, and
at least one of the second base member unit and the third base member unit is in contact with a part of one side included in the periphery of the substrate.
